(19) United States
(12) Patent Application Publication
(10) Pub. No.: US 2016/0078939 A1
(43) Pub. Date: Mar. 17, 2016

(54) APPOINTING SEMICONDUCTOR DICE TO ENABLE HIGH STACKING CAPABILITY

(71) Applicant: Intel Corporation, Santa Clara, CA (US)

(72) Inventors: Umberto Siciliani, Rubano (IT); Guido Luciano Rizzo, Albignasego (IT); Marco Carminati, Padova (IT)

(21) Appl. No.: 14/483,260

(22) Filed: Sep. 11, 2014

(51) Int. Cl. G11C 16/04; G11C 16/26

(52) U.S. Cl. CPC G11C 16/0408; G11C 16/26

(57) ABSTRACT

Briefly, in accordance with one or more embodiments, a memory array comprises two or more volumes, the volumes comprising two or more dice, respectively. The volumes are connected in a daisy chain configuration such that an output of a first volume is coupled to an input of a next volume, and the dice are connected in a daisy chain configuration such that an output of a first die is coupled to an input of a next die within the volume. In such a configuration, a first die in a first volume is capable of being appointed as part of a second volume.

### BACKGROUND

Nonvolatile memory devices such as NAND flash modules come in a variety of standard form factors having standard connectors and connector pins. As more and more storage is provided for a NAND flash module, designers have considered stacking the NAND cells to allow for greater storage capacities without increasing the footprint of the resulting memory array. Such greater sized memory arrays contain an increasing number of NAND structures formed on dies within a given target or volume. With the increasing number of dice in a memory array, each die is mapped into the volume or target through pads bonding which results in the need to add more pads a the die level and more pins at the package level in order to increase stacking parallelism. With such arrangements, volumes may be coupled together, but there is no way to appoint individual dice across multiple volumes, and initialization is only able to be performed at the target level.

### DESCRIPTION OF THE DRAWING FIGURES

Claimed subject matter is particularly pointed out and distinctly claimed in the concluding portion of the specification. However, such subject matter may be understood by reference to the following detailed description when read with the accompanying drawings in which:

FIG. 1 is a block diagram of an electronic system comprising a memory array including stacked dice in accordance with one or more embodiments;

FIG. 2 is a diagram of the memory array of FIG. 1 illustrating semiconductor dice being arranged in a daisy chain configuration in conjunction with the volumes in accordance with one or more embodiments;

FIG. 3 is diagram of one of the volumes of FIG. 2 showing the control and data lines in accordance with one or more embodiments; and

FIG. 4 is a flow diagram of a method to appoint the semiconductor dice in accordance with one or more embodiments.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components and/or circuits have not been described in detail.

In the following description and/or claims, the terms coupled and/or connected, along with their derivatives, may be used. In particular embodiments, connected may be used to indicate that two or more elements are in direct physical and/or electrical contact with each other. Coupled may mean that two or more elements are in direct physical and/or electrical contact. However, coupled may also mean that two or more elements may not be in direct contact with each other, but yet may still cooperate and/or interact with each other. For example, “coupled” may mean that two or more elements do not contact each other but are indirectly joined together via another element or intermediate elements. Finally, the terms “on,” “overlying,” and “over” may be used in the following description and claims. “On,” “overlying,” and “over” may be used to indicate that two or more elements are in direct physical contact with each other. However, “over” may also mean that two or more elements are not in direct contact with each other. For example, “over” may mean that one element is above another element but not contact each other and may have another element or elements in between the two elements. Furthermore, the term “and/or” may mean “and”, it may mean “or”, it may mean “exclusive-or”, it may mean “one”, it may mean “some, but not all”, it may mean “neither”, and/or it may mean “both”, although the scope of claimed subject matter is not limited in this respect. In the following description and/or claims, the terms “comprise” and “include,” along with their derivatives, may be used and are intended as synonyms for each other.

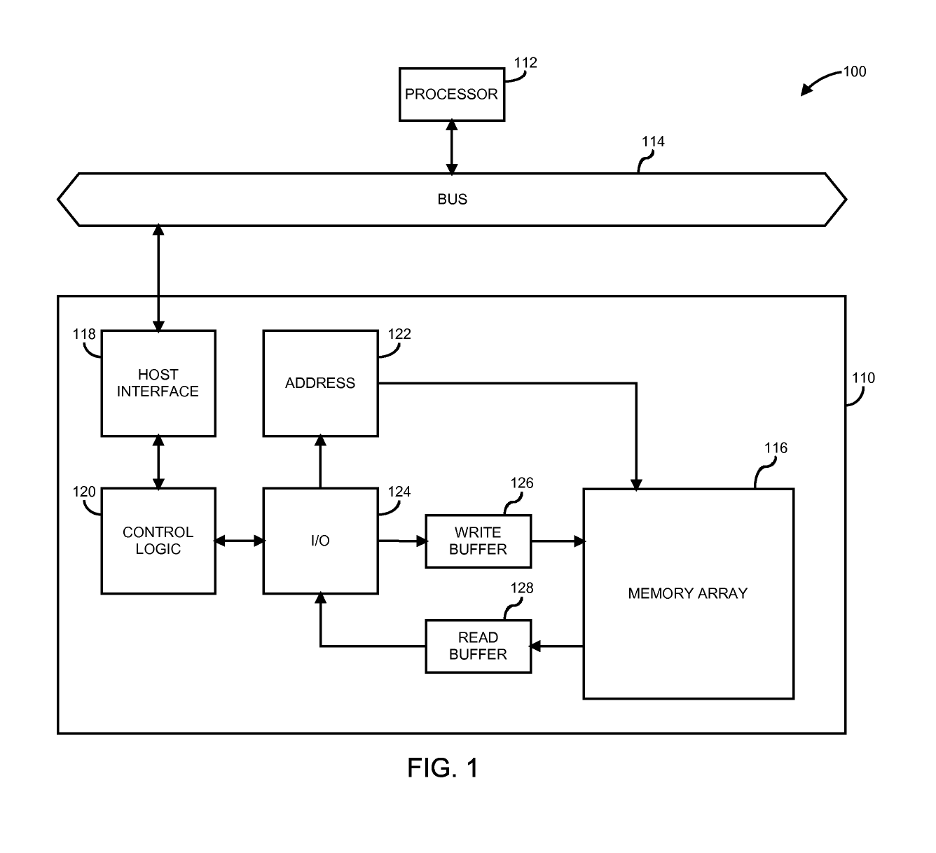

Referring now to FIG. 1, a block diagram of an electronic system comprising a memory array including stacked dice in accordance with one or more embodiments will be discussed. As shown in FIG. 1, an electronic device 100 may include a processor 112 coupled to bus 114 to couple to a memory device 110 having a memory array 116 including stacked semiconductor dice to form the memory array 116. Various embodiments of the electronic system 100 are possible other than the embodiment shown, including using a single processor 112 to control multiple memory devices 110 to provide for more storage space, multiple processors 112 connected to memory devices 110, and systems including a variety of other functionality.

In one or more embodiments, processor 112 may be coupled to memory device 110 with control lines and data lines via host interface 118. In some embodiments data and control may utilize the same lines, and the scope of the claimed subject matter is not limited in this respect. Processor 112 may be an external microprocessor, microcontroller, or some other type of external controlling circuitry. In some embodiments, processor 112 may be integrated in the same package or on the same die as the memory device 110. In some embodiments, processor 112 may be integrated with control logic 120, allowing some of the same circuitry to be used for both functions. Processor 112 may have external memory, such as RAM and/or ROM, used for program storage and/or intermediate data, and/or processor 112 may have internal RAM or ROM. In some embodiments, processor 112 may use memory device 110 for program and/or data storage. A program running on processor 112 may implement various functions including, but not limited to, a standard file system, a flash file system, write leveling, bad cell or block mapping, network communication stacks, and/or error management, and the scope of the claimed subject matter is not limited in these respects.

In some embodiments, processor 112 may communicate to external devices from which processor 112 may receive write commands and write data and store the write data in memory device 110. Processor 112 may also receive read commands from the external devices, retrieve read data from memory device 110, and send the read data to the external devices. In one embodiment wherein the electronic system 100 comprises a storage system, an external device may be provided with non-volatile storage via electronic device 100. Electronic device 100 may be a solid-state drive (SSD), a Universal Serial Bus (USB) thumb drive, or any other type of storage system. In some embodiments, processor 112 may connect to a computer or other intelligent device such as a cellular telephone, smart phone, tablet, digital camera, or the like, using a standard or a proprietary communication protocol Examples of computer communication protocols that the external connection may be compatible with include, but are not limited to, any version of the following protocols: Universal Serial Bus (USB), Serial Advanced Technology Attachment (SATA), Small Computer System Interconnect (SCSI), Fibre Channel, Parallel Advanced Technology Attachment (PATA), Integrated Drive Electronics (IDE), Ethernet, IEEE-1394, Secure Digital Card interface (SD Card), Compact Flash interface, Memory Stick interface, Peripheral Component Interconnect (PCI) or PCI Express. These are merely example types of communication protocols that may be utilized by electronic device 100, and the scope of the claimed subject matter is not limited in these respects.

In one or more embodiments, electronic system 100 may comprise a computing system or information handling system, such as a mobile telephone, a tablet, a notebook computer, a set-top box, or some other type of computing system, the external connection 402 may be a network connection such as, but not limited to, any version of the following protocols: Institute of Electrical and Electronic Engineers (IEEE) 802.3, IEEE 802.11, Data Over Cable Service Interface Specification (DOCSIS), digital television standards such as Digital Video Broadcasting (DVB)—Terrestrial, DVB-Cable, and Advanced Television Committee Standard (ATSC), and mobile telephone communication protocols such as Global System for Mobile Communication (GSM), protocols based on code division multiple access (CDMA) such as CDMA2000, Long Term Evolution (LTE), or Third Generation Partnership Project (3GPP). These are merely example types of communication protocols and/or standards that may be utilized by electronic device 100, and the scope of the claimed subject matter is not limited in these respects.

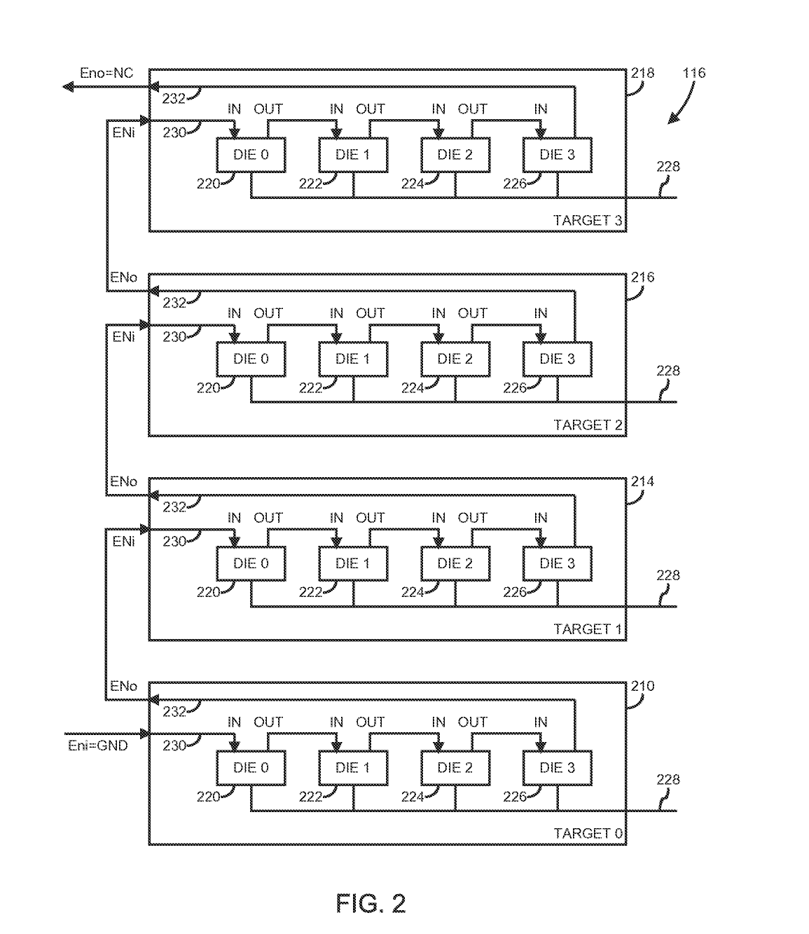

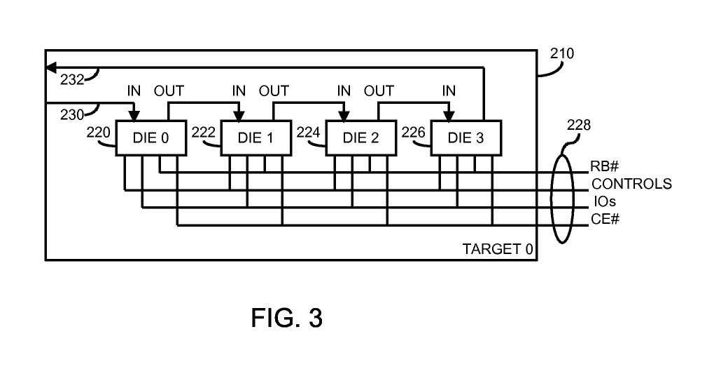

In one or more embodiments, memory device 110 includes a memory array 116 comprising an array of semiconductor dice having memory circuits stored therein and stacked in an arrangement as shown in and described with respect to FIG. 2 and FIG. 3, below. Address circuit 122 may be provided to latch address signals provided through input/output (I/O) circuit 124. Address signals may be received and decoded by a combination of address circuit 122 and control logic 120. In one or more embodiments, the number of address input connections may depends on the density and/or architecture of memory array 116 wherein the number of addresses increases with both increased memory cell counts and increased bank and block counts.

Memory device 110 may read data in memory array 116 by sensing voltage or current changes in memory array columns using sense amplifier circuitry. The sense amplifier circuitry, in one embodiment, may be coupled to read and latch a row of data from memory array 116 and communicate with read buffer 128 which may hold data read from memory array 116 until data can be sent out through data lines. Write buffer 126 may be utilized in some embodiments to accumulate data until a write can be performed and the data communicated to memory array 116. I/O circuit 124 routes the data through I/O pins of memory device 116. In some embodiments, write buffer 126 and/or read buffer 128 may be included on memory array 116.

In one or more embodiments, control logic 120 may decode commands provided on control lines from processor 112. These commands are used to control the operations on memory array 116, including data read, data write (program), and/or erase operations. Control logic 120 may comprise a state machine, a sequencer, a processor, or some other type of control logic to generate the voltage waveforms necessary to control memory array 116. Control logic 120 communicates with the other blocks in memory device 110 but those connections may not be shown. Control logic 120 may have numerous interconnections with the other blocks of memory device 110 in order to control their respective functions. The memory circuits of memory array 116 may be arranged in a stacking configuration and connected together in an arrangement that is conducive to stacking as shown in and described with respect to FIG. 2, below.

Referring now to FIG. 2, a diagram of the memory array of FIG. 1 illustrating semiconductor dice being arranged in a daisy chain configuration in conjunction with the volumes in accordance with one or more embodiments will be discussed. As shown in FIG. 2, memory array 116 of memory device 110 of FIG. 1 may comprise a group of targets or volumes, such as first target (Target 0) 210, second target (Target 1) 214, third target (Target 2) 216, and fourth target (Target 3) 218. An array of semiconductor dice may be contained within each of the respective targets, for example an array of four dice, first die (Die 0) 220, second die (Die 1) 222, third die (Die 2) 224, and fourth die (Die 3) 226. The respective targets have data and control lines 228 to couple to respective dice within a given target. Further details of the data and control lines 228 are shown in and described with respect to FIG. 3, below.

In one or more embodiments, the targets and the dice within the targets are arranged in a daisy chain configuration as shown wherein each of the targets are connected in a daisy chain such that an output 232 of one target is coupled to an input 230 of the next target. Likewise, each of the dice within a target are connected in a daisy chain such that an output (OUT) of one die is coupled to an input (IN) of the next die within the target as shown. Such an arrangement of the targets and the dice may allow for a flexible method to access the dice within a given target, and a mechanism to appoint the dice within the target or volume, to allow a new command or a new feature or sub-feature to configure the dice. As a result, stacking parallelism may be increased without the need to add more pads at die level and/or more pins at the package level. The arrangement shown in FIG. 2 allows for mapping of the dice in any possible combination wherein one die in one target may be appointed as part of another target to accommodate special needs in particular applications, and further allows Staggered Power-Up at the logical unit (LUN) level. In one more embodiments, a volume may be configured using Eni and Eno pads through Set Feature 58h in accordance with an OFNI specification. The same pads of the dice may be reused to configure the dice using a new Command or a new Set Feature or a new Sub-Feature wherein Volume Select Elh may be used to select the Volume and LUN address may be used to select the LUN. Further detail of a configuration of the dice within an example volume is shown in and described with respect to FIG. 3, below.

Referring now to FIG. 3, a diagram of one of the volumes of FIG. 2 showing the control and data lines in accordance with one or more embodiments will be discussed. As an example, first target (Target 0) 210 is shown comprising four dice, first die (Die 0) 220, second die (Die 1) 222, third die (Die 2) 224, and fourth die (Die 3) 226. Target 210 further includes an input 230 and an output 232 to couple to the dice in a daisy chain configuration. Furthermore, data and control lines 228 may comprise a group of individual lines such as a ready/busy (RB#) line, a control (CONTROLS), an input/output line (I/O), and a chip enable (CE#) line, as some examples, in accordance with an Open NAND Flash Interface (ONFI) specification, although the scope of the claimed subject matter is not limited in these respects. In one or more embodiments, RB# line is an open-drain output pin of a die that is capable of providing a ready/busy status of a read/program/erase operation of the die. In one or more embodiments, CONTROLS line provides an input one or more control commands, for example a command latch enable input or an address latch enable input. In one or more embodiments, I/O line comprises one or more pines for address and/or command input to the die, and read data to or from the die. In one or more embodiments, CE# allows a die to be selected for a read operation or deselected to place the die into standby. Although target 210 of FIG. 3 comprises four dice in a daisy chain configuration as shown, target 210 may have various other numbers of dice, and/or various configurations to connect the dice, and the scope of the claimed subject matter is not limited in these respects.

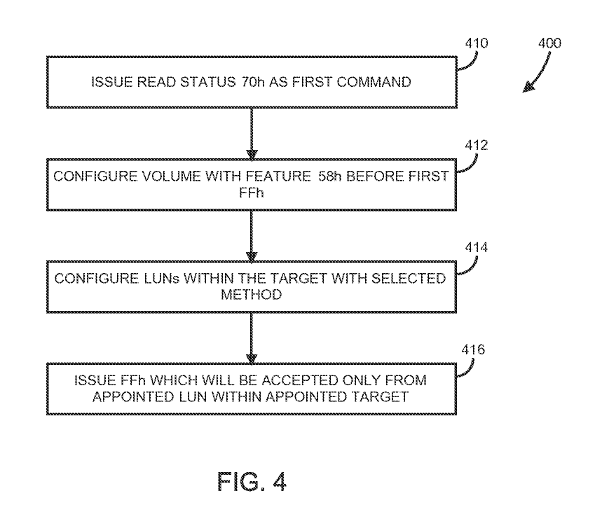

Referring now to FIG. 4, a flow diagram of a method to appoint the semiconductor dice in accordance with one or more embodiments will be discussed. Although method FIG. 4 shows one order and number of blocks for method 400, method 400 may include more or fewer blocks than shown, and in various other orders, and the scope of the claimed subject matter it not limited in these respects. In one or more embodiments, method 400 allows for staggered device initialization as a logical unit (LUN) level as follows. Furthermore, in one or more embodiments, method 400 may be implemented in accordance with an ONFI standard, although the scope of the claimed subject matter is not limited in this respect. A read status 70h may be issues as a first command at block 410. A target (volume) may be configured at block 412 with feature 58h before a first FFh. Logical units (LUNs) may be configured at block 414 within a selected target. At block 416 the FFh may be issued which will be accepted only from an appointed LUN within the appointed target. Using method 400 an example initialization sequence with a reuse of Set Feature 58h is as follows:

Appoint a first target (Target 0) 210 and LUN0,1,2,3 within Target 0:
EFh 58h; P1=00h; P2=00h (Die 0 is set as LUN0)
EFh 58h; P1=00h; P2=01h (Die 1 is set as LUN1)
EFh 58h; P1=00h; P2=02h (Die 2 is set as LUN2)
EFh 58h; P1=00h; P2=03h (Die 3 is set as LUN3)

Appoint a second target (Target 1) and LUN0,1,2,3 within Target 1:
EFh 58h; P1=01h; P2=00h (Die 0 is set as LUN0)
EFh 58h; P1=01h; P2=01h (Die 1 is set as LUN1)
EFh 58h; P1=01h; P2=02h (Die 2 is set as LUN2)
EFh 58h; P1=01h; P2=03h (Die 3 is set as LUN3)

Although the claimed subject matter has been described with a certain degree of particularity, it should be recognized that elements thereof may be altered by persons skilled in the art without departing from the spirit and/or scope of claimed subject matter. It is believed that the subject matter pertaining to appointing semiconductor dice to enable high stacking capability and many of its attendant utilities will be understood by the forgoing description, and it will be apparent that various changes may be made in the form, construction and/or arrangement of the components thereof without departing from the scope and/or spirit of the claimed subject matter or without sacrificing all of its material advantages, the form herein before described being merely an explanatory embodiment thereof, and/or further without providing substantial change thereto. It is the intention of the claims to encompass and/or include such changes.

What is claimed is:

1. A memory array comprising:
two or more volumes, the volumes comprising two or more dice, respectively;
wherein the volumes are connected in a daisy chain configuration such that an output of a first volume is coupled to an input of a next volume; and
wherein the dice are connected in a daisy chain configuration such that an output of a first die is coupled to an input of a next die within the volume.

2. A memory array as claimed in claim 1, wherein the volumes are disposed in a stacked configuration.

3. A memory device as claimed in claim 1, wherein the daisy chain configuration of the dice is part of the daisy chain configuration of the volumes such that an input of a volume is coupled to an input of a first die within the volume and an output of a last die of the volume is coupled to an output of the volume.

4. A memory array as claimed in claim 1, wherein a first die in a first volume is capable of being appointed as part of a second volume.

5. A memory array as claimed in claim 1, wherein the dice may be powered up in a staggered order a logical unit level.

6. A method to appoint dice within a memory array, comprising:
issuing a read status as a first command;
configuring a volume with Feature 58h before a first FFh;
configuring one or more logical units within the volume; and
issuing the first FFh.

7. A method as claimed in claim 6, wherein the first FFh issued will accepted only from an appointed logical unit within the configured volume.

8. A method as claimed in claim 6, further comprising appointing a first die in another volume as part of the configured volume.

9. A method as claimed in claim 6, further comprising powering one or more dice in a staggered order in the volume or in another volume, or a combination thereof, at a logical unit level.

10. A method as claimed in claim 6, wherein one or more dice within the configured volume and one or more device within another volume may be initialized in any selected order.

11. A solid state drive (SSD), comprising:
a host interface to couple to a processor via the host interface;
control logic coupled to the host interface; and
a memory array coupled to the control logic, wherein the memory array comprises:
two or more volumes, the volumes comprising two or more dice, respectively;
wherein the volumes are connected in a daisy chain configuration such that an output of a first volume is coupled to an input of a next volume; and
wherein the dice are connected in a daisy chain configuration such that an output of a first die is coupled to an input of a next die within the volume.

12. A solid state drive as claimed in claim 11, wherein the volumes are disposed in a stacked configuration.

13. A solid state drive as claimed in claim 11, wherein the daisy chain configuration of the dice is part of the daisy chain configuration of the volumes such that an input of a volume is coupled to an input of a first die within the volume and an output of a last die of the volume is coupled to an output of the volume.

14. A solid state drive as claimed in claim 11, wherein a first die in a first volume is capable of being appointed as part of a second volume.

15. A solid state drive as claimed in claim 11, wherein the dice may be powered up in a staggered order a logical unit level.

16. An article of manufacture comprising a non-transitory machine-readable medium having instructions stored thereon to appoint dice within a memory array that, if executed, result in:
issuing a read status as a first command;
configuring a volume with Feature 58h before a first FFh;
configuring one or more logical units within the volume; and
issuing the first FFh.

17. An article of manufacture as claimed in claim 6, wherein the first FFh issued will accepted only from an appointed logical unit within the configured volume.

18. An article of manufacture as claimed in claim 6, wherein the instructions, if executed, further result in appointing a first die in another volume as part of the configured volume.

19. An article of manufacture as claimed in claim 6, wherein the instructions, if executed, further result in powering one or more dice in a staggered order in the volume or in another volume, or a combination thereof, at a logical unit level.

20. An article of manufacture as claimed in claim 6, wherein one or more dice within the configured volume and one or more device within another volume may be initialized in any selected order
